(19) United States
(12) Patent Application Publication
(10) Pub. No.: US 2023/0395449 A1
(43) Pub. Date: Dec. 7, 2023

(54) METHOD AND APPARATUS FOR FORMING SEMICONDUCTOR DEVICE

(71) Applicant: STATS ChipPAC Pte. Ltd., Singapore (SG)

(72) Inventors: SeungHyun LEE, Incheon (KR); HyeonChul LEE, Incheon (KR); YuJin HWANG, Bushan (KR); DaYoung KWON, Incheon (KR)

(21) Appl. No.: 18/328,795

(22) Filed: Jun. 5, 2023

(30) Foreign Application Priority Data
Jun. 7, 2022 (CN) 202210637493.4

(51) Int. Cl. H01L 23/31; H01L 21/56; H01L 23/00

(52) U.S. Cl. CPC H01L 23/3128; H01L 21/565; H01L 24/32; H01L 2924/3025; H01L 2224/32225

(57) ABSTRACT

A method for forming a semiconductor device is provided. The method include: providing a package including: a substrate; a stress absorbing layer disposed on a top surface of the substrate; an electronic component mounted on the top surface of substrate; and a first contact pad disposed on the top surface of the substrate and exposed from the stress absorbing layer; providing a mold including: a first cavity exposed from a bottom surface of the mold; and a recess formed adjacent to the first cavity; engaging the mold and the package with the first cavity over the electronic component and the recess between the electronic component and the first contact pad; and injecting encapsulation material into the first cavity to form an encapsulant over the electronic component.

### TECHNICAL FIELD

The present application generally relates to semiconductor technology, and more particularly, to a method and an apparatus for forming a semiconductor device.

### BACKGROUND OF THE INVENTION

The semiconductor industry is constantly faced with complex integration challenges as consumers want their electronics to be smaller, faster and higher performance with more and more functionalities packed into a single device. Antenna-in-Package (AiP) has emerged as the mainstream antenna packaging technology for various applications. The AiP allows integration of an antenna and a RF chip (e.g., transceiver) in a single package. The AiP can be further integrated with front-end components (e.g., power amplifiers (PA) or low-noise amplifiers (LNA)), switches, filters and even power management integrated circuit (PMIC) to form an antenna module using System-in-Package (SiP) technologies. However, the package yield is still low in SiP.

Therefore, a need exists for a reliable semiconductor device.

### SUMMARY OF THE INVENTION

An objective of the present application is to provide a method for making a semiconductor device with high reliability.

According to an aspect of embodiments of the present application, a method for forming a semiconductor device is provided. The method may include: providing a package including: a substrate; a stress absorbing layer disposed on a top surface of the substrate; an electronic component mounted on the top surface of substrate; and a first contact pad disposed on the top surface of the substrate and exposed from the stress absorbing layer; providing a mold including: a first cavity exposed from a bottom surface of the mold; and a recess formed adjacent to the first cavity; engaging the mold and the package with the first cavity over the electronic component and the recess between the electronic component and the first contact pad; and injecting encapsulation material into the first cavity to form an encapsulant over the electronic component.

According to another aspect of embodiments of the present application, a molding apparatus for forming an encapsulant on a package is provided. The molding apparatus may include: a mold, wherein the mold including: a first cavity exposed from a bottom surface of the mold; and a recess formed adjacent to the first cavity; wherein the package includes: a substrate; a stress absorbing layer disposed on a top surface of the substrate; an electronic component mounted on the top surface of substrate; and a first contact pad disposed on the top surface of the substrate and exposed from the stress absorbing layer; and wherein the mold is configured for engaging the package with the first cavity over the electronic component and the recess between the electronic component and the first contact pad, and encapsulation material can be injected into the first cavity to form the encapsulant over the electronic component.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1A is a cross-sectional view of a package.

FIG. 1B is a microscopic image of a package.

FIG. 2A and FIG. 2B are cross-sectional views of a package and a mold used in forming the package according to an embodiment of the present application.

FIG. 3 is a microscopic image of the package of FIG. 2B.

FIG. 4 is another microscopic image of the package of FIG. 2B.

FIG. 5 is an enlarged view of a portion of the package and the mold in FIG. 2B according to an embodiment of the present application.

FIG. 6 is an enlarged view of a portion of the package and the mold in FIG. 2B according to another embodiment of the present application.

FIG. 7 is a cross-sectional view of a mold according to another embodiment of the present application.

FIG. 8 is a cross-sectional view of a mold according to another embodiment of the present application.

FIG. 9 is a flowchart illustrating a method for forming a semiconductor device according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

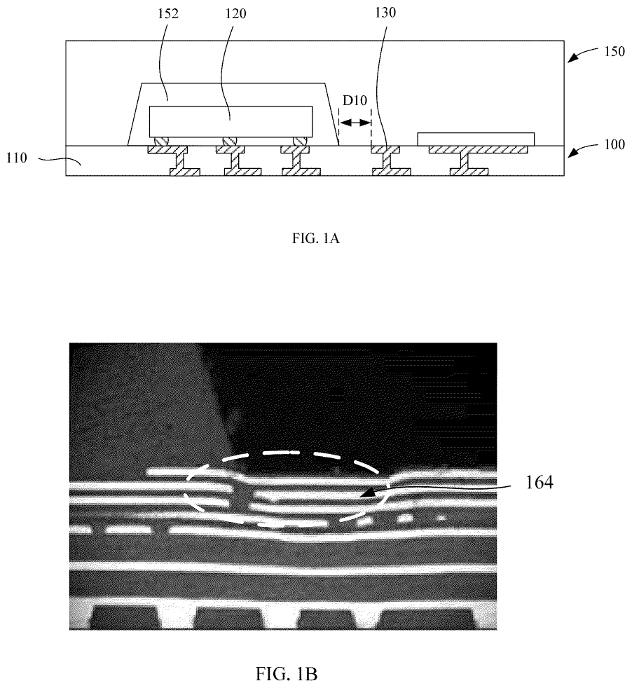

Referring now to FIG. 1A, a cross-sectional view of a package 100 and a mold 150 is illustrated. The mold 150 can be used during the manufacturing of the package 100, as will be elaborated below. The package 100 includes a substrate 110 and an electronic component 120 mounted on the substrate 110. A plurality of contact pads can be formed on the top surface of the substrate 110. Specifically, as shown in FIG. 1A, there is a contact pad 130 adjacent to the electronic component 120. The contact pad 130 may be used for connection to an external electrical component or structure, for example, a solder ball or an electromagnetic interference (EMI) shield. The mold 150 has a cavity 152, which may be used to accommodate the electronic component 120 during a molding process. Thus, when the mold 150 is placed on and engages with the substrate 110, the electronic component 120 is accommodated within the cavity 152 of the mold 150. Then, an encapsulation material may be injected into the cavity 152 to form an encapsulant over the electronic component 120 to protect the electronic component 120 from external environment.

However, there is always a short clearance between the electronic component 120 and the contact pad 130, for example, the dimension D10 shown in FIG. 1A. It is noted that, in a conventional molding process, the contact pad is likely to be invaded by mold flash because of the short clearance. The mold flash can obscure the contact pad 130, which can lead to poor or faulty electrical interconnections. The poor or faulty electrical interconnections can cause low package yield upon integration into consumer products.

Further, in order to secure the mold to the package during the molding process, a securing mechanism may be used, which may apply a clamping force on the package through the mold attached thereto. Accordingly, in the molding process, a stress may be caused in the substrate 110 by the applied force, and the substrate 110 and contact pads formed therein may be damaged due to the deformation by stress. FIG. 1B is a microscopic image of a package, in which deformations of the substrate and contact pads can be found (as indicated by the dashed circle 164 in FIG. 1B). The deformations of the substrate and contact pads may also cause low package yield.

To address at least one of the above problems, in the embodiments of the present application, a method for forming a semiconductor device is provided. In the method, a mold and a package are strategically engineered and designed to prevent or minimize the mold flash and the deformation of substrate. The mold includes a recess formed adjacent to a cavity for accommodating an electronic component of the package. The package includes a stress absorbing layer disposed on a substrate. When the mold and the package are engaged with each other, the cavity of the mold accommodates the electronic component of the package, and the recess of the mold is between the electronic component and the contact pad of the package. The recess can act as a collection reservoir for mold flash that would normally bleed between the mold and the package, and thus prevent the contact pad from the mold flash. The stress absorbing layer can absorb the stress caused by the clamping force induced into the package, and thus reduce the deformation of the substrate and the contact pads. Therefore, the package yield can be improved by the method of the present application.

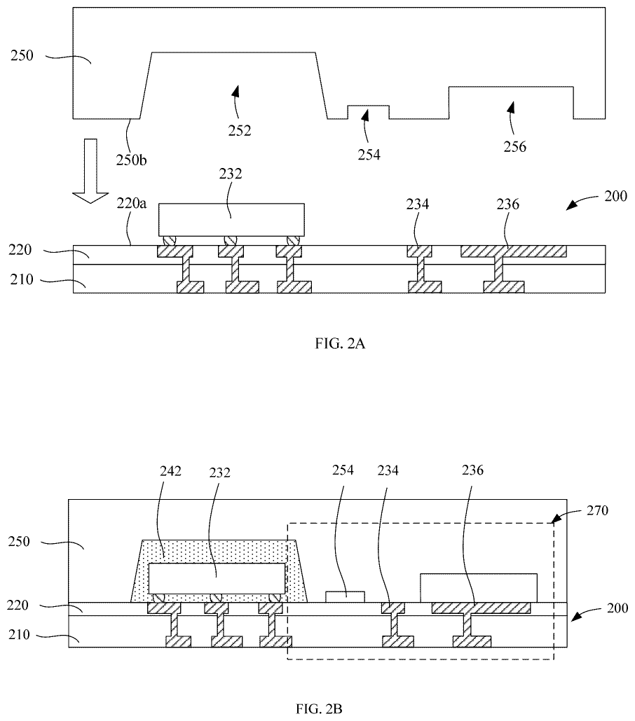

Referring now to FIG. 2A and 2B, FIG. 2A illustrates a cross-sectional view of a package 200 and a mold 250 according to an embodiment of the present application, and FIG. 2B shows that the package 200 and the mold 250 of FIG. 2A are engaged with each other, and an encapsulant is formed over an electronic component of the package 200.

As shown in FIG. 2A, the package 200 include a substrate 210, a stress absorbing layer 220, an electronic component 232 and a first contact pad 234. The stress absorbing layer 220 is disposed on a top surface of the substrate 210, the electronic component 232 is mounted on the top surface of substrate 210, and the first contact pad 234 is also disposed on the top surface of the substrate 210 and is exposed from the stress absorbing layer 220.

The substrate 210 can support the electronic component 232. The substrate 210 may also support and electrically interconnect additional packages formed thereover. By way of example, the substrate 210 may include a printed wiring board or a semiconductor substrate; however, the substrate 210 is not to be limited to these examples. In other examples, the substrate 210 may be a laminate interposer, a strip interposer, a leadframe, or other suitable substrates. In accordance with the scope of the present invention, the substrate 210 may include any structure on or in which integrated circuit systems are fabricated. For example, the substrate 210 may include one or more insulating or passivation layers, one or more conductive vias formed through the insulating layers, and one or more conductive layers formed over or between the insulating layers. In the example shown in FIG. 2A, a redistribution structure (RDS) is formed in the substrate 210, which include a plurality of top conductive patterns on the top surface of the substrate 210, a plurality of bottom conductive patterns on the bottom surface of the substrate 210, and a plurality of conductive vias electrically connecting at least one of the top conductive patterns with at least one of the bottom conductive patterns.

The electronic component 232 may be mounted on the top surface of the substrate 210. For example, the electronic component 232 may be mounted on the top surface of the substrate 210 via the top conductive patterns of the RDS. However, the present application is not limited to this example. The electronic component 232 may include semiconductor chips, integrated circuit systems, and integrated circuit packages selected from active components, passive components, stacked components, memory components, and so forth, in numerous configurations and arrangements as may be needed. It can be understood that the electronic component 232 covers a wide range of semiconductor chip, integrated circuit system, and integrated circuit package configurations involving various sizes, dimensions, and electrical contact techniques (e.g., surface mounting or wire bonding).

As shown in FIG. 2A, a first contact pad 234 is also formed on the top surface of the substrate 210. The first contact pad 234 may be electrically connected with conductive traces, conductive vias, or other conductive structures in the substrate 210. The first contact pad 234 may include one or more of Al, Cu, Sn, Ni, Au, Ag, or other suitable electrically conductive material. In some embodiments, the first contact pad 234 may be connected with a solder ball or a bump to provide an electrical connection to external elements or devices. In some embodiments, the first contact pad 234 may be connected with an EMI shield.

The stress absorbing layer 220 is formed on the top surface of the substrate 210. The electronic component 232 and the first contact pad 234 are exposed from the stress absorbing layer 220. In some embodiments, the stress absorbing layer may include solder resist (SR), which is also referred as solder mask. The solder resist may be made of various photosensitive resin compositions or various heat curable resin compositions, and is generally used to ensure that solder is only deposited where required (e.g., on the conductive patterns exposed from the solder resist) and to protect the top surface of the substrate. In some embodiments, the stress absorbing layer 220 may include other materials having sufficient properties such as hardness, heat resistance, chemical resistance, electrical insulation reliability, flexibility, and/or toughness. The stress absorbing layer 220 is shown as a single layer in FIG. 2A. However, in other examples, the stress absorbing layer 220 may be a multi-layer laminate.

The mold 250 includes a first cavity 252 and a recess 254. The first cavity 252 is formed in the mold 250 and exposed from a bottom surface 250b of the mold 250. The recess 254 is formed adjacent to the first cavity 252. In applications, the position and shape of the recess 254 may be determined according to the layout of the package 200 for which the mold 250 may be used. The mold 250 may be included in a molding apparatus, and the molding apparatus may further include a securing mechanism (not shown) for engaging the mold 250 to the package 200.

Referring to FIG. 2A and 2B together, the mold 250 can engage a top surface 220a of the stress absorbing layer 220, such that the first cavity 252 can accommodate the electronic component 232 and the recess 254 is between the electronic component 232 and the first contact pad 234. Then, an encapsulation material (for example, an epoxy-based resin, or other polymer composite material) can be injected into the first cavity 252 to form an encapsulant 242 surrounding the electronic component 232 for protection purpose. For example, a mold gate and an air vent may be located at two opposite sides of the mold 250 respectively, and both are in fluid communication with the first cavity 252. The encapsulation material can be injected into the first cavity 252 through the mold gate, and the air vent may allow displaced air to escape from the mold 250 during the injection of the encapsulation material. In the example shown in FIG. 2B, the sidewall of the first cavity 252 is slanted to facilitate the release (or disengagement) of the mold 250 from the package 200. It can be understood that the configuration of the cavity 252 can be designed to accommodate or fit over any structure that requires a mold encapsulation.

The recess 254 may be formed continuously along a perimeter of the first cavity 252, or may be formed in areas likely to suffer from mold flash. In other words, the recess 254 can be formed continuously, intermittently, or on one or more sides around the first cavity 252. However, it is to be understood that the recess 254 can be formed in any configuration or design that helps to prevent mold flash problems by collecting mold flash. Although the recess 254 is depicted as having a cross section shaped as a square in FIG. 2A, the recess 254 may be formed in another shape, as long as the recess 254 includes a hollow space in which mold flash may accumulate.

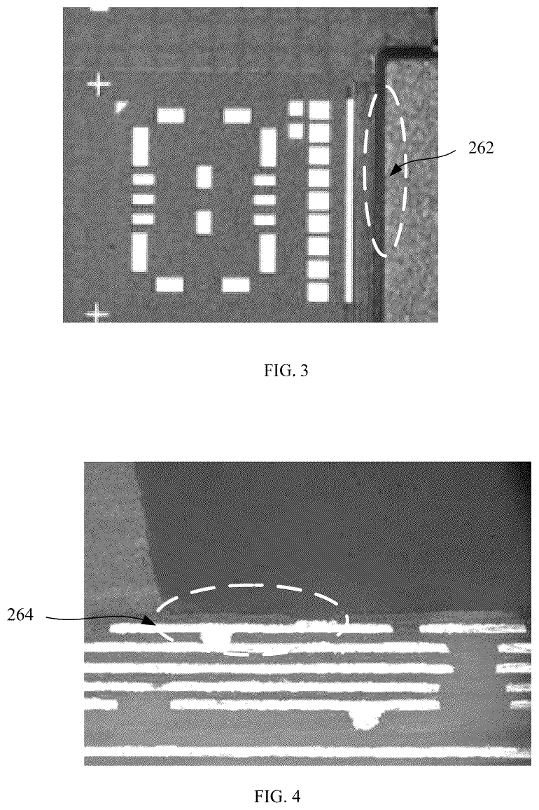

The inventors of the present application have found that the recess 254 can act as a collection reservoir for mold flash that would normally bleed between the bottom surface 250b of the mold 250 and the top surface 220a of the stress absorbing layer 220. Consequently, any of the encapsulation material that escapes from the first cavity 252 is trapped within the recess 254 and does not obscure or contaminate the first contact pad 234. FIG. 3 is a microscopic image of a semiconductor device formed according to an embodiment of the present invention. As can be seen, no mold flash can be detected in the contact pad area (as indicated by the dashed circle 262 in FIG. 3), thereby improving product yield by preventing device failure due to failed or weakened electrical interconnects.

As shown in FIG. 2B, when the mold 250 and the package 200 are engaged with each other, a clamping force may be applied on the package 200 through the mold 250 to ensure a secure contact therebetween. That is, the bottom surface 250b of the mold 250 may abut against the top surface 220b of the stress absorbing layer 220, and a seal can be formed between the mold 250 and the stress absorbing layer 220.

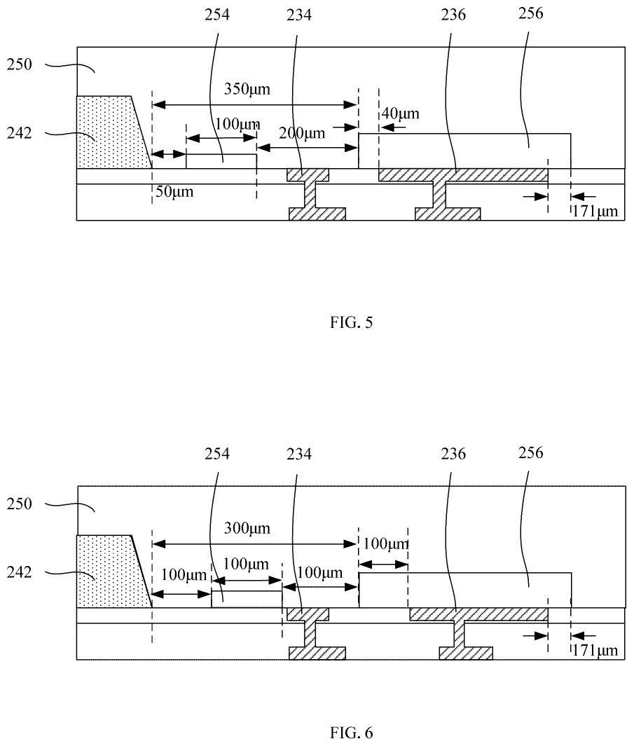

The inventors of the present application have found that the seal between the mold 250 and the stress absorbing layer 220 can further prevent the bleeding of the encapsulation material, and the stress absorbing layer 220 can effectively absorb or diffuse the stress caused by the clamping force, and thus reduce deformations of various components in the package 200. FIG. 4 is a microscopic image of a semiconductor device formed according to an embodiment of the present invention. As can be seen, the substrate or contact pad is not deformed after the molding process (as indicated by the dashed circle 264 in FIG. 4), thereby improving product yield by preventing device failure due to failed or weakened electrical interconnects.

Notably, in order to effectively absorb the stress in the package 200, a thickness of the tress absorbing layer 220 may be significantly larger than that of a conventional solder resist layer. In some embodiments, the thickness of the tress absorbing layer 220 may be 1.5 times to 5 times the thickness of the conventional solder resist layer. In some embodiments, the thickness of the stress absorbing layer 220 ranges from 20 μm to 100 μm, for example, 25 μm, 30 μm, 40 μm, 50 μm, 60 μm, 70 μm, 80 μm or 90 μm. However, the thickness of the stress absorbing layer 220 is not to be limited to these examples. In accordance with the scope of the present application, the thickness of the tress absorbing layer 22 may include any thickness, which can effectively absorb the stress in the package 200.

Continuing referring to FIG. 2A and FIG. 2B, the package 200 further includes a second contact pad 236, and the second contact pad 236 is farther away from the electronic component 232 than the first contact pad 234. The mold 250 also includes a second cavity 256 corresponding to the second contact pad 236. When the mold 250 and the package 200 are engaged with each other, the second cavity 256 is disposed over the second contact pad 236.

In some embodiments, the electronic component 232 may be a transceiver device that uses antenna to convert between an electromagnetic radiation signal sent or received over the airwaves and an electrical signal within the electronic component 232. The transceiver functionality of the electronic component 232 will be facilitated by not having a conformal EMI shielding layer formed over the antenna, which could block desirable signals. In some embodiments, the second contact pad 236 may be a board-to-board (B2B) pad to connect the package 200 and another semiconductor package including memory or logic circuits. The semiconductor package may be molded in an encapsulant prior to mounting on the B2B pad. The B2B pad can provide electrical connections between two packages, which can ease signal routing requirements of electrical devices and provide faster and more direct signal transmission. As the memory or logic circuits in the semiconductor package mounted on the B2B pad may benefit from an EMI shielding layer, a conformal EMI shielding layer can be formed over this semiconductor package. In some embodiments, the first contact pad 234 may be a ground pad, which is electrically coupled to a ground node through conductive connections. The EMI shielding layer can be formed over the semiconductor package and coupled to the first contact pad 234 to aid in EMI blocking capability.

However, the present application is not limited to the above examples, and the electronic component 232 and the package mounted on the second contact pad 236 can include any combination of any type of semiconductor package, semiconductor die, integrated passive device, discrete active or passive components, or other electrical components.

FIG. 5 illustrates an enlarged view of the portion 270 of FIG. 2B according to an embodiment. FIG. 5 depicts a portion of the package 200 including a portion of the encapsulant 242, the first contact pad 234 and the second contact pad 236, and a portion of the mold 250 including the recess 254 and the second cavity 256.

FIG. 5 depicts various distance dimensions. For example, a distance between the encapsulant 242 and the left sidewall of the recess 254 is 50 μm, the recess 254 has a width of 100 μm, and a distance between the right sidewall of the recess 254 and the left sidewall of the second cavity 256 is 200 μm. That is, a distance between the encapsulant 242 and the left sidewall of the second cavity 256 is 350 μm. Further, a distance between the left sidewall of the second cavity 256 and the left edge of the second contact pad 236 is 40 μm, and a distance between the right edge of the second contact pad 236 and the right sidewall of the second cavity 256 is 171 μm.

With the above strategically designed dimensions of the package 200 and the mold 250, a test is carried out under the following conditions: a clamping force of 60 ton, a thickness of the stress absorbing layer 220 being 28 μm, and a depth of the recess 254 being 25 μm. The results show that no mold flash is detected in the contact pad area, and the substrate and the contact pads are not deformed after the molding process.

Although FIG. 5 depicts various distance dimensions, it can be understood that these distance dimensions are merely exemplary and are not intended to limit the scope of the present invention.

For example, FIG. 6 illustrates an enlarged view of the portion 270 of FIG. 2B according to another embodiment. As shown in FIG. 6, a distance between the encapsulant 242 and the left sidewall of the recess 254 is 100 μm, the recess 254 has a width of 100 μm, and a distance between the right sidewall of the recess 254 and the left sidewall of the second cavity 256 is 100 μm. That is, a distance between the encapsulant 242 and the left sidewall of the second cavity 256 is 300 μm. Further, a distance between the left sidewall of the second cavity 256 and the left edge of the second contact pad 236 is 100 μm, and a distance between the right edge of the second contact pad 236 and the right sidewall of the second cavity 256 is 171 μm.

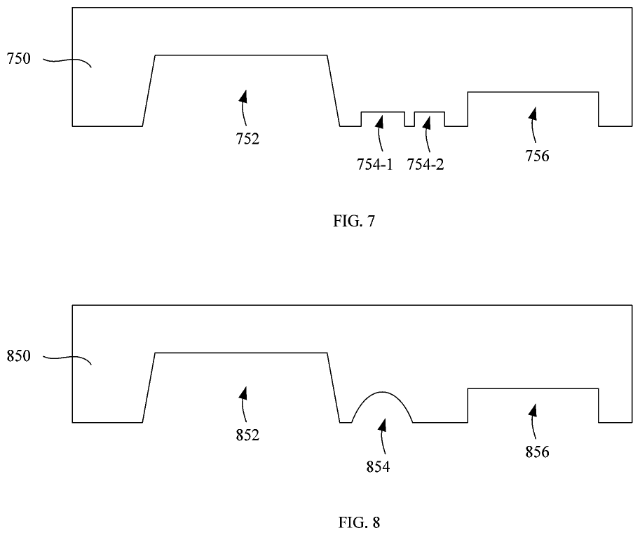

Referring to FIG. 7, a cross-sectional view of a mold 750 is illustrated according to another embodiment of the present application. The mold 750 can be used in place of the mold 250 of FIGS. 2A and 2B.

The mold 750 includes a first cavity 752, a second cavity 756, and two recesses 754-1 and 754-2 between the cavities 752 and 756. By forming a second recess 754-2 adjacent to the first recess 752-1, any mold flash that is not captured by the first recess 752-1 can be collected or retained by the second recess 754-2. The second recess 754-2 acts as an additional collection reservoir for mold flash, and therefore, further prevents the dispersion or flashing of the encapsulation material.

It could be understood that the mold 750 is not limited to the two recesses 754-1 and 754-2 configuration. In accordance with the scope of the present application, the mold 750 may include any number of cavities or similar structures, which help to prevent the contamination of the contact pad by mold flash.

Referring now to FIG. 8, a cross sectional view of a mold 850 is shown according to another embodiment of the present application. The mold 850 can also be used in place of the mold 250 of FIGS. 2A and 2B.

The mold 850 includes a first cavity 852, a recess 854, and a second cavity 856. The recess 854 is formed to have a cross sectional shape of a circle or oval. However, this example is not to be construed as limiting, and the design or shape of the recess may include any curved or arced configuration, or any poly-sided configuration. In accordance with the scope of the present invention, it is to be understood that the recess may include any design or shape, as long as the recess include a hollow space in which mold flash may accumulate. For example, the recess may have an opening (i.e., where the sidewall of the recess is in contact with the substrate of the package) that is narrower or smaller than the internal space of the recess. As such, the recess may be able to collect as much as mold flash while not occupying too much footprint on the substrate of the package.

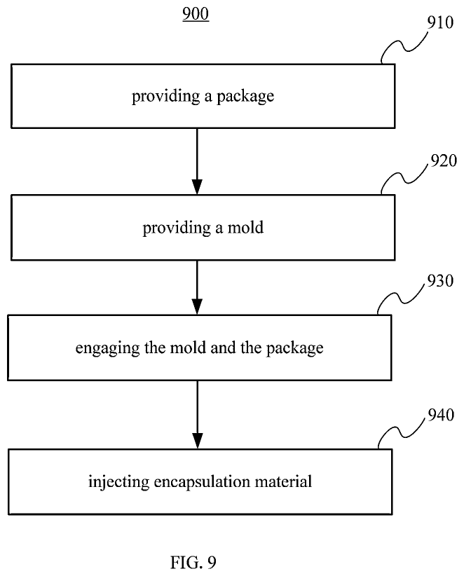

Referring to FIG. 9, a method 900 for forming a semiconductor device is illustrated according to an embodiment of the present application. For example, the method 900 may use the mold 250 shown in FIG. 2A and FIG. 2B, the mold 750 shown in FIG. 7 or the mold 850 shown in FIG. 8 to form a semiconductor device.

As illustrated in FIG. 9, the method 900 may start with providing a package in block 910. The package may include a substrate, a stress absorbing layer disposed on a top surface of the substrate, an electronic component mounted on the top surface of substrate, and a first contact pad disposed on the top surface of the substrate and exposed from the stress absorbing layer. Afterwards, in block 920, a mold is provided. The mold may include a first cavity exposed from a bottom surface of the mold, and a recess formed adjacent to the first cavity. Afterwards, in block 930, the mold and the package may be engaged. After the mold and the package are engaged, the first cavity is over the electronic component and the recess is between the electronic component and the first contact pad. At last, in block 940, encapsulation material is injected into the first cavity to form an encapsulant over the electronic component.

More details about the method 900 may be referred to the disclosure and drawings about the mold and the package disclosed above, and will not will not be elaborated herein.

The discussion herein included numerous illustrative figures that showed various portions of a semiconductor device and a method of manufacturing thereof. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for forming a semiconductor device, comprising:
providing a package comprising:
a substrate;
a stress absorbing layer disposed on a top surface of the substrate;
an electronic component mounted on the top surface of substrate; and
a first contact pad disposed on the top surface of the substrate and exposed from the stress absorbing layer;
providing a mold comprising:
a first cavity exposed from a bottom surface of the mold; and
a recess formed adjacent to the first cavity;
engaging the mold and the package with the first cavity over the electronic component and the recess between the electronic component and the first contact pad; and
injecting encapsulation material into the first cavity to form an encapsulant over the electronic component.

2. The method of claim 1, wherein the stress absorbing layer comprises solder resist.

3. The method of claim 1, wherein a thickness of the stress absorbing layer ranges from 20 μm to 100 μm.

4. The method of claim 1, wherein the bottom surface of the mold compresses the stress absorbing layer when the mold and the package are engaged.

5. The method of claim 1, wherein the recess is formed around a perimeter of the first cavity.

6. The method of claim 1, wherein the package further comprises a second contact pad, and the first contact pad is between the electronic component and the second contact pad.

7. The method of claim 6, wherein the mold further comprises a second cavity, and when the mold and the package are engaged, the second cavity is over the second contact pad.

8. The method of claim 7, wherein the first contact pad is a ground pad, and the second contact pad is a board-to-board pad.

9. A molding apparatus for forming an encapsulant on a package, comprising:
a mold, wherein the mold comprising:
a first cavity exposed from a bottom surface of the mold; and
a recess formed adjacent to the first cavity;
wherein the package comprises: a substrate; a stress absorbing layer disposed on a top surface of the substrate; an electronic component mounted on the top surface of substrate;
and a first contact pad disposed on the top surface of the substrate and exposed from the stress absorbing layer; and
wherein the mold is configured for engaging the package with the first cavity over the electronic component and the recess between the electronic component and the first contact pad, and encapsulation material can be injected into the first cavity to form the encapsulant over the electronic component.

10. The molding apparatus of claim 9, wherein the stress absorbing layer comprises solder resist.

11. The molding apparatus of claim 9, wherein a thickness of the stress absorbing layer ranges from 20 μm to 100 μm.

12. The molding apparatus of claim 9, wherein the bottom surface of the mold compresses the stress absorbing layer when the mold and the package are engaged.

13. The molding apparatus of claim 9, wherein the recess is formed around a perimeter of the first cavity.

14. The molding apparatus of claim 9, wherein the package further comprises a second contact pad, and the first contact pad is between the electronic component and the second contact pad.

15. The molding apparatus of claim 14, wherein the mold further comprises a second cavity, and when the mold and the package are engaged, the second cavity is over the second contact pad.

16. The molding apparatus of claim 15, wherein the first contact pad is a ground pad, and the second contact pad is a board-to-board pad.
